(19) United States
(12) Patent Application Publication
(10) Pub. No.: US 2019/0131153 A1
(43) Pub. Date: May 2, 2019

(54) APPARATUS AND METHOD FOR MONITORING SUBSTRATE PROCESSING

(71) Applicant: SEMES CO., LTD., Chungcheongnam-do (KR)

(72) Inventors: YOUNG HUN JUNG, Hwaseong-si (KR); JINHWAN KIM, Hwaseong-si (KR)

(21) Appl. No.: 16/168,890

(22) Filed: Oct. 24, 2018

(30) Foreign Application Priority Data
Oct. 26, 2017 (KR) 10-2017-0140253

(51) Int. Cl. H01L 21/67; H01L 21/66; G06K 9/62

(52) U.S. Cl. CPC H01L 21/67253; G06K 9/6267; H01L 22/12

(57) ABSTRACT

Disclosed is an apparatus for monitoring substrate processing, the apparatus including a process data acquisition unit that acquires process data regarding the substrate processing from substrate processing equipment, a storage unit that stores screen configuration data regarding a process monitoring screen that is configured to match a layout of the substrate processing equipment, a processing unit that imports the screen configuration data and operates the process monitoring screen according to the process data, and a control unit that classifies the process data according to time points and outputs a process data value at a specific time point on the process monitoring screen.

### CROSS-REFERENCE TO RELATED APPLICATIONS

A claim for priority under 35 U.S.C. § 119 is made to Korean Patent Application No. 10-2017-0140253 filed on Oct. 26, 2017, in the Korean Intellectual Property Office, the entire contents of which are hereby incorporated by reference.

### BACKGROUND

Embodiments of the inventive concept described herein relate to an apparatus and method for monitoring substrate processing, and more particularly, relate to a substrate processing monitoring apparatus and method for outputting process data at a specific time point.

Substrate processing, such as forming a circuit pattern on a substrate (e.g., a silicon wafer or glass), is performed by substrate processing equipment designed to meet requirements for the substrate processing. The substrate processing equipment includes various kinds of modules required to process substrates.

For example, in the case where the substrate processing equipment performs a photolithography process to form a circuit pattern on a substrate, the substrate processing equipment includes modules for performing unit processes required for the photolithography process, such as a coating module for coating the substrate with a photosensitive material, an exposure module for exposing the substrate coated with the photosensitive material to light, a developing module for developing the exposed substrate, and the like.

Substrate processing by the substrate processing equipment is a series of processes in which a plurality of substrates are processed according to a predetermined recipe. In the order of the processes, the modules in the substrate processing equipment receive a substrate from a module for performing processing corresponding to the previous step, perform predetermined processing on the substrate, and transfer the substrate to a module for performing processing corresponding to the next step.

As described above, the modules in the substrate processing equipment are combined together to perform substrate processing, and an operator needs to find out whether the substrate processing is performed normally in the substrate processing equipment. If the substrate processing equipment shuts down due to an abnormality in a part thereof, the operator determines the cause of the problem based on records or data relating to the substrate processing performed in the substrate processing equipment, solves the problem, restores the locations of substrates and the statuses of the modules in the substrate processing equipment to the former locations and statuses, and restarts the substrate processing equipment.

That is, the operator directly determines the cause of the problem with the substrate processing equipment. Therefore, a large amount of time may be required to find out the cause of the problem, and an analysis result may vary with the operator's proficiency or understanding of the substrate processing equipment.

### SUMMARY

Embodiments of the inventive concept provide a substrate processing monitoring apparatus and method for determining whether there is an abnormality in substrate processing equipment, thereby enabling a user to easily discern problems with the substrate processing equipment.

According to an aspect of an embodiment, an apparatus for monitoring substrate processing includes a process data acquisition unit that acquires process data regarding the substrate processing from substrate processing equipment, a storage unit that stores screen configuration data regarding a process monitoring screen that is configured to match a layout of the substrate processing equipment, a processing unit that imports the screen configuration data and operates the process monitoring screen according to the process data, and a control unit that classifies the process data according to time points and outputs a process data value at a specific time point on the process monitoring screen.

According to an embodiment, the control unit may compare the process data with a pre-stored normal status value to determine whether the substrate processing equipment is abnormal or not, and when it is determined that the substrate processing equipment is abnormal, the control unit may output the process monitoring screen at a time point when the abnormality occurred in the substrate processing equipment.

According to an embodiment, the process data acquisition unit may acquire the process data indicating an event that occurs in at least one module included in the substrate processing equipment as the substrate processing is performed.

According to an embodiment, the process data may include module identification data for identifying the module in which the event occurs, event identification data for identifying the event, event start time data regarding time when the event starts, and event end time data regarding time when the event ends.

According to an embodiment, the storage unit may store the screen configuration data regarding at least one component included in the process monitoring screen to correspond to at least one module included in the substrate processing equipment and an arrangement of the at least one component in the process monitoring screen.

According to an embodiment, the screen configuration data may be configured such that the at least one component is disposed in the process monitoring screen in an order of the at least one module through which a substrate passes along a transfer path in the substrate processing equipment.

According to an embodiment, the processing unit may generate a process monitoring chart showing a status of a substrate processed by the substrate processing equipment during the substrate processing over time.

According to an embodiment, the screen configuration data may be configured such that the at least one component is disposed on a side of the process monitoring screen and the process monitoring chart at the time point when the abnormality occurred in the substrate processing equipment and the process monitoring chart at a current time point are disposed on an opposite side of the process monitoring screen.

According to another aspect of an embodiment, a method for monitoring, by a substrate processing monitoring apparatus, substrate processing performed in substrate processing equipment includes acquiring process data regarding the substrate processing from the substrate processing equipment, importing screen configuration data regarding a process monitoring screen that is configured to match a layout of the substrate processing equipment, operating the process monitoring screen according to the process data, based on the screen configuration data, and classifying the process data according to time points and outputting a process data value at a specific time point on the process monitoring screen.

According to an embodiment, the outputting of the process data value at the specific time point on the process monitoring screen may include comparing the process data with a pre-stored normal status value to determine whether the substrate processing equipment is abnormal or not and outputting the process monitoring screen at a time point when the abnormality occurred in the substrate processing equipment, when it is determined that the substrate processing equipment is abnormal.

According to an embodiment, the acquiring of the process data may include acquiring the process data indicating an event that occurs in at least one module included in the substrate processing equipment as the substrate processing is performed.

According to an embodiment, the process data may include module identification data for identifying the module in which the event occurs, event identification data for identifying the event, event start time data regarding time when the event starts, and event end time data regarding time when the event ends.

According to an embodiment, the importing of the screen configuration data may include importing the screen configuration data regarding at least one component included in the process monitoring screen to correspond to at least one module included in the substrate processing equipment and an arrangement of the at least one component in the process monitoring screen.

According to an embodiment, the screen configuration data may be configured such that the at least one component is disposed in the process monitoring screen in an order of the at least one module through which a substrate passes along a transfer path in the substrate processing equipment.

According to an embodiment, the operating of the process monitoring screen may include configuring the process monitoring screen in which the at least one component is disposed, based on the screen configuration data and modifying a visual state of the at least one component corresponding to the at least one module according to data indicating an event of the at least one module that is included in the process data.

According to an embodiment, the method may further include generating a process monitoring chart showing a status of at least one substrate processed by the substrate processing equipment during the substrate processing over time.

According to an embodiment, the screen configuration data may be configured such that the at least one component is disposed on a side of the process monitoring screen and the process monitoring chart at the time point when the abnormality occurred in the substrate processing equipment and the process monitoring chart at a current time point are disposed on an opposite side of the process monitoring screen.

According to an embodiment, the generating of the process monitoring chart may include generating the process monitoring chart by displaying time according to the progress of the substrate processing along one axis of the process monitoring chart and displaying the status of the at least one substrate along another axis of the process monitoring chart.

According to another aspect of an embodiment, a recording medium is a computer-readable recording medium that stores a program for executing the method for monitoring the substrate processing.

According to another aspect of an embodiment, a program is a computer program stored in a recording medium to execute the method for monitoring the substrate processing.

According to various embodiments of the inventive concept, substrate processing can be efficiently monitored, and a user can easily discern when and where an abnormality occurs in substrate processing equipment.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic block diagram illustrating a substrate processing system according to an embodiment of the inventive concept;

FIG. 2 is a plan view illustrating the structure of substrate processing equipment according to an embodiment of the inventive concept;

FIG. 3 is a block diagram illustrating a substrate processing monitoring apparatus according to an embodiment of the inventive concept;

FIG. 4 is a view illustrating the configuration of a process monitoring screen according to an embodiment of the inventive concept;

FIGS. 5 and 6 are views illustrating a process of modifying the visual state of a component corresponding to a module, based on data indicating an event of the module, according to an embodiment of the inventive concept;

FIG. 7 is a view illustrating an operation of displaying components, in which substrates belonging to one substrate group are distributed, differently from the other components, according to an embodiment of the inventive concept;

FIG. 8 is a view illustrating an operation of displaying details of a module corresponding to a selected component according to an embodiment of the inventive concept;

FIG. 9 is a view illustrating the configuration of a process monitoring screen according to another embodiment of the inventive concept; and

FIG. 10 is a flowchart illustrating a method for monitoring substrate processing according to an embodiment of the inventive concept.

### DETAILED DESCRIPTION

Hereinafter, embodiments of the inventive concept will be described in detail with reference to the accompanying drawings.

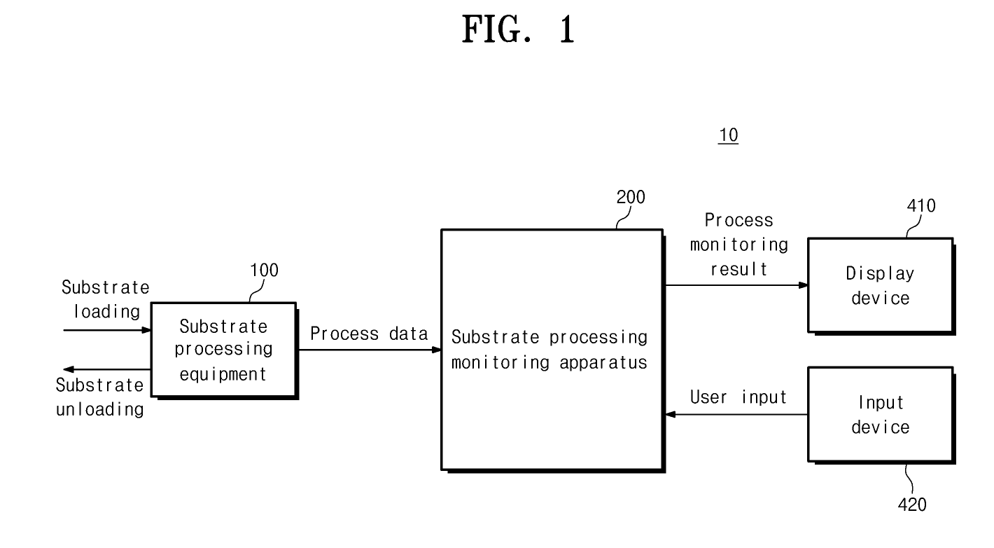

FIG. 1 is a schematic block diagram illustrating a substrate processing system 10 according to an embodiment of the inventive concept.

As illustrated in FIG. 1, the substrate processing system 10 may include substrate processing equipment 100, a substrate processing monitoring apparatus 200, and a display device 410.

The substrate processing equipment 100 may process substrates and may include one or more modules required to perform the substrate processing.

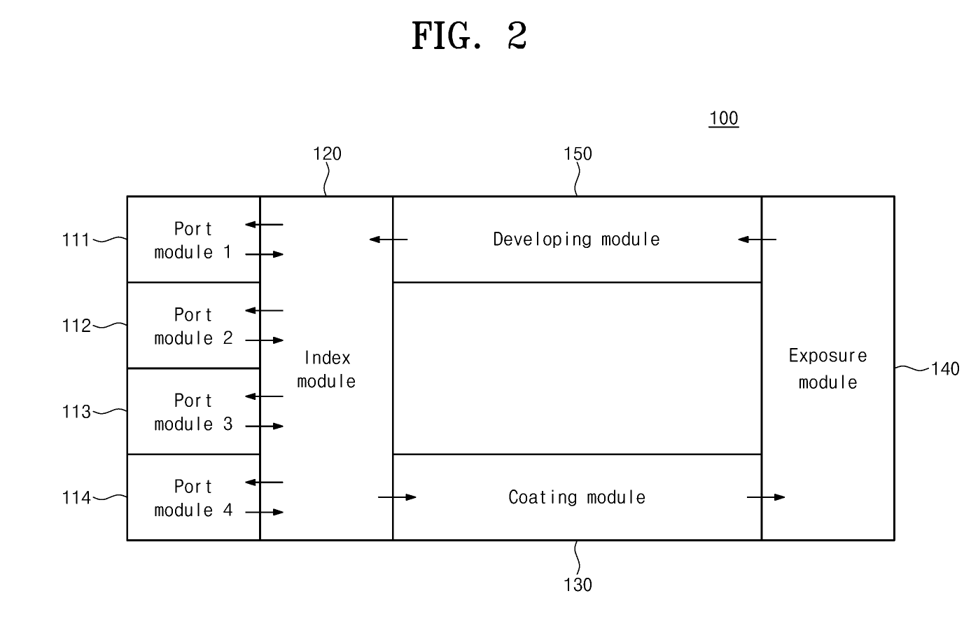

FIG. 2 is a plan view illustrating the structure of the substrate processing equipment 100 according to an embodiment of the inventive concept.

As illustrated in FIG. 2, the substrate processing equipment 100 may include one or more modules and may perform substrate processing. For example, in the case where the substrate processing equipment 100 performs a photolithography process, the substrate processing equipment 100 may include one or more port modules 111, 112, 113, and 114, an index module 120, a coating module 130, an exposure module 140, and a developing module 150.

The port modules 111, 112, 113, and 114 may receive substrates therein when the substrates are loaded into or unloaded from the substrate processing equipment 100. The port modules 111, 112, 113, and 114 may be located at the front end of the substrate processing equipment 100. The coating module 130 may coat a substrate with a photosensitive material. For example, the coating module 130 may include a coating apparatus for coating a substrate with photoresist. The exposure module 140 may expose the substrate coated with the photosensitive material to light. For example, the exposure module 140 may irradiate light, such as UV light, to the substrate coated with the photosensitive material in a predetermined pattern using a stepper. The developing module 150 may develop the exposed substrate. For example, the developing module 150 may apply a developing solution to the exposed substrate to develop the exposed substrate. The index module 120 may transfer substrates between the port modules 111, 112, 113, and 114 and the coating module 130 or the developing module 150. For example, the index module 120 may transfer substrates from the port modules 111, 112, 113, and 114 to the coating module 130 or from the developing module 150 to the port modules 111, 112, 113, and 114 by using a substrate transfer robot.

In the substrate processing equipment 100 for photolithography, which is illustrated in FIG. 2, a substrate may be transferred in the order of the port module 111, 112, 113, or 114, the index module 120, the coating module 130, the exposure module 140, the developing module 150, the index module 120, and the port module 111, 112, 113, or 114, and each module may perform predetermined processing on the substrate. The direction in which the substrate is transferred in the substrate processing equipment 100 may be represented by arrows.

The above-described substrate processing equipment 100 may be equipment for performing a photolithography process. The substrate processing equipment 100 to be monitored according to embodiments of the inventive concept is not limited to the configuration illustrated in FIG. 2. The types and structures of modules included in the substrate processing equipment 100 may vary depending on the types of processes performed on substrates.

The substrate processing equipment 100 may process a display panel, for example, a glass substrate. However, the type of substrate processed by the substrate processing equipment 100 is not limited thereto. For example, the substrate processing equipment 100 may also process a semiconductor wafer.

The substrate processing monitoring apparatus 200 may monitor substrate processing performed in the substrate processing equipment 100.

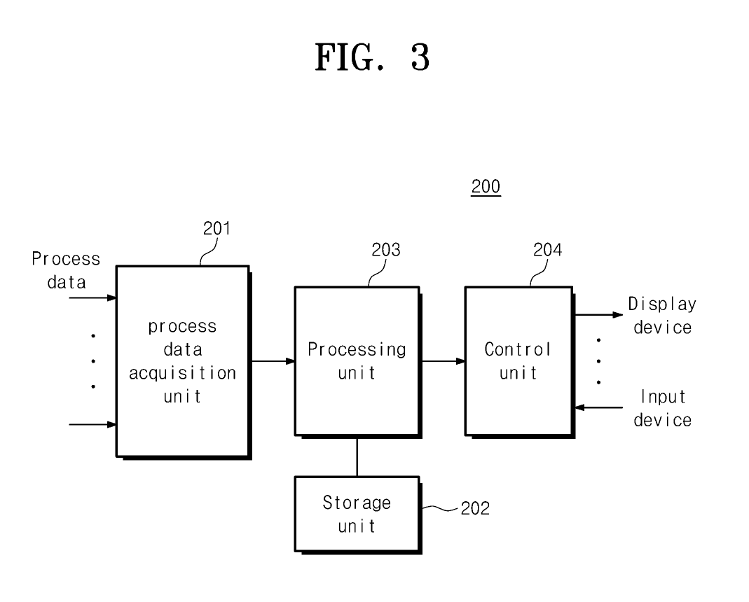

FIG. 3 is a block diagram illustrating the substrate processing monitoring apparatus 200 according to an embodiment of the inventive concept.

As illustrated in FIG. 3, the substrate processing monitoring apparatus 200 according to the embodiment of the inventive concept may include a process data acquisition unit 201, a storage unit 202, a processing unit 203, and a control unit 204.

The process data acquisition unit 201 may acquire process data regarding substrate processing from the substrate processing equipment 100. The storage unit 202 may store screen configuration data regarding a process monitoring screen that is configured to match the layout of the substrate processing equipment 100. The processing unit 203 may import the screen configuration data and may operate the process monitoring screen according to the process data. The control unit 204 may classify the process data according to time points and may output a process data value at a specific time point on the process monitoring screen.

The process data acquisition unit 201 may receive the process data from the substrate processing equipment 100. For example, the process data acquisition unit 201 may receive process data regarding substrate processing from a sensor installed in each module of the substrate processing equipment 100. In this case, the process data acquisition unit 201 may include a communication device wiredly or wirelessly connected to the substrate processing equipment 100 to receive the process data.

The storage unit 202 may be a storage device for storing data. The storage unit 202 may store various types of data required to perform operations of the substrate processing monitoring apparatus 200, for example, processing of process data for process monitoring, the configuration of the process monitoring screen, and operation of the process monitoring screen. The storage unit 202 may include a storage device, such as an HDD or an SSD, for storing a large amount of data. Without being limited thereto, however, the storage unit 202 may include a storage device, such as memory, a cache, or a register, for storing a small amount of data.

The processing unit 203 may process data. The processing unit 203 may execute a program made in advance to perform process monitoring and may generate monitoring result data correspondingly. The processing unit 203 may include a CPU, a controller, or the like. The processing unit 203 may process the process data according to a predetermined algorithm and may configure and operate the process monitoring screen correspondingly, thereby generating monitoring result data.

The control unit 204 may be a processor that processes data. The control unit 204 may classify the process data according to time points by using the monitoring result data generated by the processing unit 203 and may output a process data value at a specific time point on the process monitoring screen. The control unit 204 may include a CPU, a controller, or the like. The control unit 204, along with the processing unit 203, may be implemented to be a single device. Furthermore, the control unit 204 may compare the process data with a pre-stored normal status value to determine whether the substrate processing equipment 100 is abnormal or not. In the case where the substrate processing equipment 100 is abnormal, the control unit 204 may output a process monitoring screen at the time point when the abnormality occurred in the substrate processing equipment 100. Accordingly, a user may easily discern where and when the abnormality occurred in the substrate processing equipment 100.

The monitoring result data generated by the substrate processing monitoring apparatus 200 may be provided to the user through an output device, for example, the display device 410 illustrated in FIG. 1. The display device 410 may include a display, which may be, for example, an LCD or a PDP. The display device 410 may provide the monitoring result data to the user by visually displaying the monitoring result data on a screen thereof.

In addition, as illustrated in FIG. 1, the substrate processing system 10 may further include an input device 420. The substrate processing system 10 may receive a user input for process monitoring from the user via the input device 420. The user may enter a command or data via the input device 420 such as a keyboard, a mouse, a touchpad, or a touch screen to control operations of the substrate processing monitoring apparatus 200.

According to an embodiment, the process data acquisition unit 201 may acquire process data indicating an event that occurs in at least one module included in the substrate processing equipment 100 as substrate processing is performed. In other words, the process data acquired by the process data acquisition unit 201 may be information about the event that occurs in the module included in the substrate processing equipment 100.

According to an embodiment, the process data may include module identification data for identifying the module in which the event occurs and event identification data for identifying the event.

For example, the module identification data may be an identifier, such as the ID of a module in which a predetermined event occurs during substrate processing. The event identification data may be an identifier, such as the ID indicating the type of an event that occurs at present in the module, among events that are likely to occur in the module.

As described above, the process data may include the module identification data for specifying the module in which the event occurs and the event identification data for specifying the event. Accordingly, the process data may allow the substrate processing monitoring apparatus 200 to recognize the subject that generates the event and the type of the event.

According to an embodiment of the inventive concept, the event identification data may include at least one piece of normal status data that corresponds to at least one normal status that the module has in relation to the substrate. In other words, the normal status data may indicate one or more statuses that the module has in relation to the substrate when the module operates normally.

For example, the normal status data may include at least one of a non-operating status in which no substrate is loaded in the module and the module does not operate, a standby status in which no substrate is loaded in the module and the module stands ready for operating, an operating status in which the substrate is loaded in the module and the module is operating, an operation end status in which the substrate is loaded in the module and the module stops operating, and a substrate transfer status in which the substrate is loaded into or unloaded from the module.

As described above, the normal status data may describe one or more statuses, considering whether the substrate is located in the module and whether the module operates.

According to another embodiment, the event identification data may include alarm data for providing notification that the module is in a predetermined abnormal status. In this case, the event identification data may not describe a normal operation status of the module, but may notify of occurrence of an abnormal situation, such as a failure.

The condition for allowing the substrate processing equipment 100 to send the alarm data may be determined in advance and may be applied to the substrate processing equipment 100. In the case where the condition is satisfied, the substrate processing equipment 100 may transmit the alarm data to the substrate processing monitoring apparatus 200.

According to an embodiment, the process data provided by the substrate processing equipment 100 may further include event start time data regarding the time when the event starts and event end time data regarding the time when the event ends, in addition to the module identification data and the event identification data. In this case, the substrate processing monitoring apparatus 200 may recognize the start time and the end time of the event, as well as the module in which the event occurs and the type of the event.

However, unlike in the above-described embodiment, the substrate processing monitoring apparatus 200 may not receive the event start time data and the event end time data from the substrate processing equipment 100, but may receive process data in real time from the substrate processing equipment 100. In this case, the substrate processing monitoring apparatus 200 may determine process data reception time to be event start time and may determine the next process data reception time to be event end time.

The storage unit 202 may store the screen configuration data regarding the process monitoring screen that is configured to match the layout of the substrate processing equipment 100.

According to an embodiment of the inventive concept, the storage unit 202 may store the screen configuration data regarding at least one component included in the process monitoring screen to correspond to at least one module included in the substrate processing equipment 100 and the arrangement of the component in the process monitoring screen. That is, the screen configuration data may describe contents regarding the component included in the process monitoring screen and the arrangement of the component. For example, the screen configuration data may be configured such that the component is disposed on a side of the process monitoring screen and a process monitoring chart at the time point when an abnormality occurred in the substrate processing equipment 100 and a process monitoring chart at the current time point are disposed on an opposite side of the process monitoring screen.

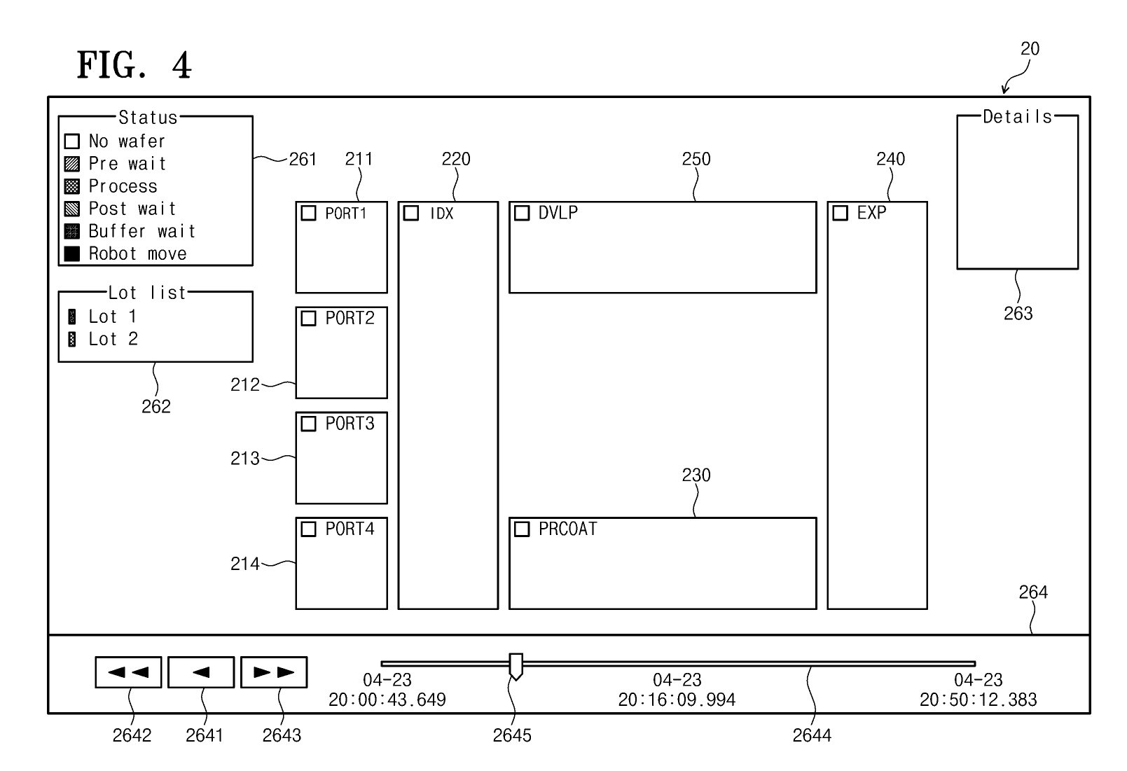

FIG. 4 is a view illustrating the configuration of a process monitoring screen 20 according to an embodiment of the inventive concept.

As illustrated in FIG. 4, the process monitoring screen 20 may include one or more components 211, 212, 213, 214, 220, 230, 240, and 250. The components 211, 212, 213, 214, 220, 230, 240, and 250 may be arranged to correspond to the layout of the substrate processing equipment 100.

Compared with the layout of the substrate processing equipment 100 illustrated in FIG. 2, the components 211, 212, 213, 214, 220, 230, 240, and 250 in the process monitoring screen 20 may correspond to the modules 111, 112, 113, 114, 120, 130, 140, and 150 included in the substrate processing equipment 100, respectively.

Specifically, the components 211, 212, 213, and 214 in the process monitoring screen 20 may correspond to the port modules 111, 112, 113, and 114 of the substrate processing equipment 100, respectively, and the components 220, 230, 240, and 250 may correspond to the index module 120, the coating module 130, the exposure module 140, and the developing module 150, respectively.

The components 211, 212, 213, 214, 220, 230, 240, and 250 may be arranged in the process monitoring screen 20 in the order of the modules 111, 112, 113, 114, 120, 130, 140, and 150 through which a substrate passes along a transfer path in the substrate processing equipment 100. In FIG. 4, the components 211, 212, 213, 214, 220, 230, 240, and 250 in the process monitoring screen 20 may be arranged in the same manner as the planar arrangement of the modules 111, 112, 113, 114, 120, 130, 140, and 150 of the substrate processing equipment 100 illustrated in FIG. 2.

However, in the inventive concept, the arrangement of the components 211, 212, 213, 214, 220, 230, 240, and 250 in the process monitoring screen 20 does not necessarily have to be structurally the same as the planar arrangement of the modules 111, 112, 113, 114, 120, 130, 140, and 150 of the substrate processing equipment 100. As described above, the components 211, 212, 213, 214, 220, 230, 240, and 250 may be arranged in the process monitoring screen 20 in the order of the modules 111, 112, 113, 114, 120, 130, 140, and 150 through which the substrate passes along the transfer path in the substrate processing equipment 100, as long as the modules 111, 112, 113, 114, 120, 130, 140, and 150 of the substrate processing equipment 100 correspond to the components 211, 212, 213, 214, 220, 230, 240, and 250 in the process monitoring screen 20, respectively.

According to an embodiment of the inventive concept, the processing unit 203 may configure the process monitoring screen 20, in which the components 211, 212, 213, 214, 220, 230, 240, and 250 are arranged, based on the screen configuration data and may modify the visual states of the components 211, 212, 213, 214, 220, 230, 240, and 250 corresponding to the modules 111, 112, 113, 114, 120, 130, 140, and 150 according to data indicating events of the modules 111, 112, 113, 114, 120, 130, 140, and 150 that is included in process data.

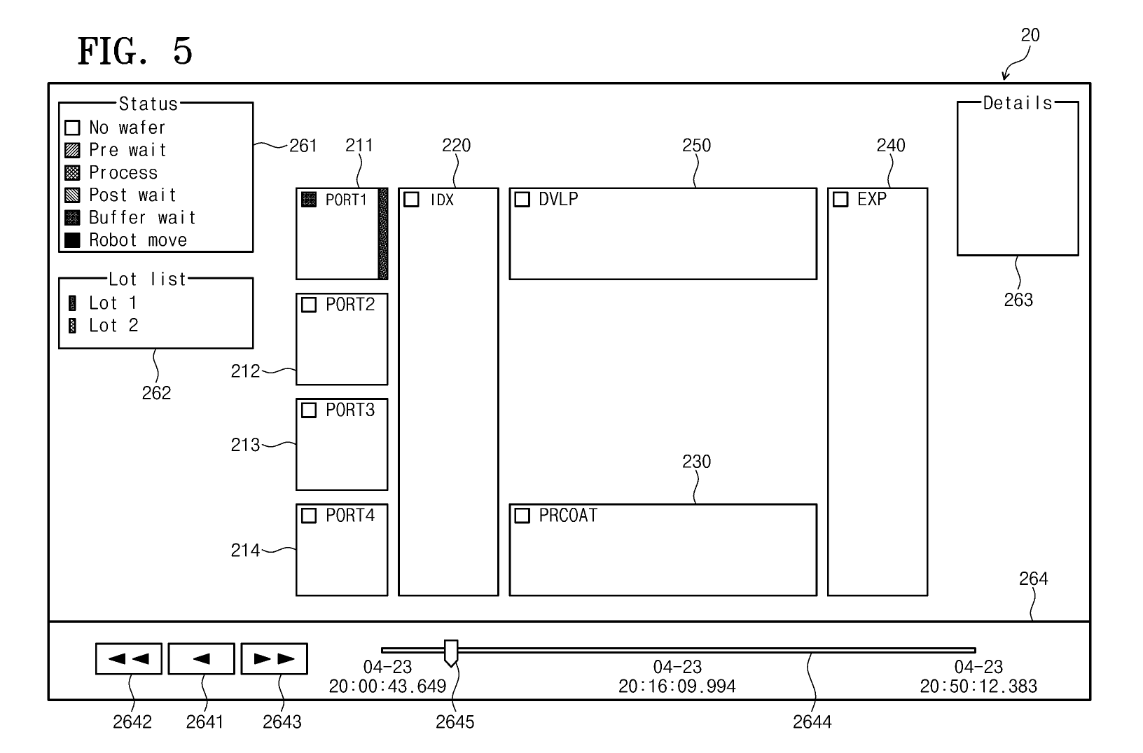

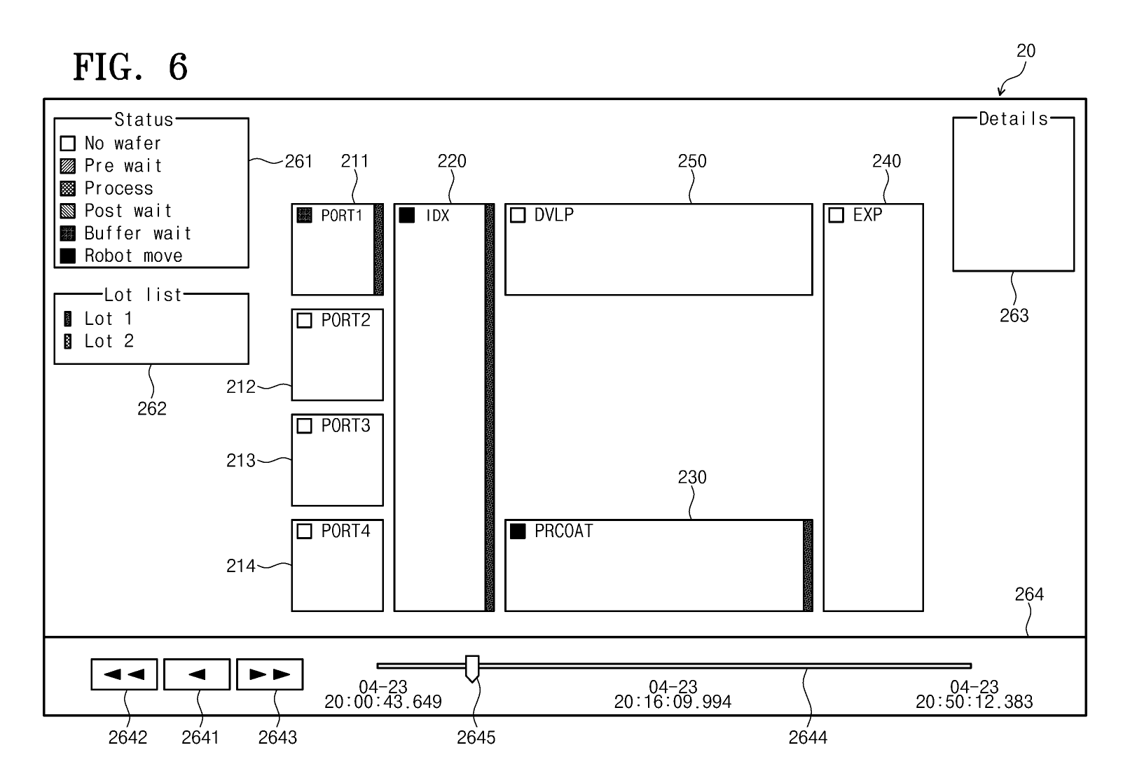

FIGS. 5 and 6 are views illustrating a process of modifying the visual state of a component corresponding to a module, based on data indicating an event of the module, according to an embodiment of the inventive concept.

As described above with reference to FIG. 4, the processing unit 203 may configure the process monitoring screen 20, in which the components 211, 212, 213, 214, 220, 230, 240, and 250 are arranged, based on the screen configuration data stored in the storage unit 202.

The processing unit 203 may modify the visual states of the components 211, 212, 213, 214, 220, 230, 240, and 250 corresponding to the modules 111, 112, 113, 114, 120, 130, 140, and 150 according to data indicating events of the modules 111, 112, 113, 114, 120, 130, 140, and 150 that is included in process data.

For example, referring to FIGS. 2 and 5, when a substrate is loaded in the first port module 111 of the substrate processing equipment 100, the substrate processing equipment 100 may transmit, to the substrate processing monitoring apparatus 200, process data including a message for providing notification that the substrate is loaded and stored in the first port module 111, and the processing unit 203 may modify the visual state of the PORT 1 component 211 corresponding to the first port module 111 according to the message included in the process data.

Unlike in the process monitoring screen 20 of FIG. 4, the colorless upper left area of the PORT 1 component 211 may change to a predetermined color in the process monitoring screen 20 of FIG. 5. The color change of the area in the PORT 1 component 211 may show that the first port module 111 corresponding to the PORT 1 component 211 is in a state corresponding to the relevant color.

In this regard, referring to FIG. 4, the process monitoring screen 20 may provide a status list 261 that includes visual states to be assigned to the components 211, 212, 213, 214, 220, 230, 240, and 250 (e.g., colors of partial areas in the components) and the statuses of the modules 111, 112, 113, 114, 120, 130, 140, and 150 that correspond to the visual states.

As described above with reference to FIG. 5, the processing unit 203 may modify the visual states of the components 211, 212, 213, 214, 220, 230, 240, and 250 in the process monitoring screen 20 (e.g., the colors of partial areas such as the upper left areas of the components) to one in the status list 261 according to the message included in the process data, thereby visually displaying the statuses of the modules 111, 112, 113, 114, 120, 130, 140, and 150 in the substrate processing equipment 100 that correspond to the components 211, 212, 213, 214, 220, 230, 240, and 250.

Referring to FIGS. 2 and 6, when the substrate loaded in the first port module 111 is transferred to the coating module 130 via the index module 120, the substrate processing equipment 100 may transmit, to the substrate processing monitoring apparatus 200, process data including a message for providing notification that the index module 120 operates and a robot transfers the substrate to the coating module 130, and the processing unit 203 may modify the visual states of the IDX component 220 corresponding to the index module 120 and the PRCOAT component 230 corresponding to the coating module 130 to one in the status list 261 according to the message included in the process data.

As described above, the substrate processing monitoring apparatus 200 may acquire process data from the substrate processing equipment 100 as substrate processing is performed in the substrate processing equipment 100, and may modify the visual states of the components 211, 212, 213, 214, 220, 230, 240, and 250 in the process monitoring screen 20 according to the acquired process data, thereby visually displaying the statuses of the modules 111, 112, 113, 114, 120, 130, 140, and 150 in the substrate processing equipment 100 that correspond to the components 211, 212, 213, 214, 220, 230, 240, and 250.

A user may view the process monitoring screen 20, which is provided by the substrate processing monitoring screen 200, through the display device 410 to easily monitor the substrate processing performed in the substrate processing equipment 100 and discern at a glance the process in which the substrate is transferred and processed in the substrate processing equipment 100.

According to another embodiment of the inventive concept, among the components 211, 212, 213, 214, 220, 230, 240, and 250, components in which a plurality of substrates belonging to a substrate group processed with the same recipe are distributed may be displayed differently from the other components by the processing unit 203.

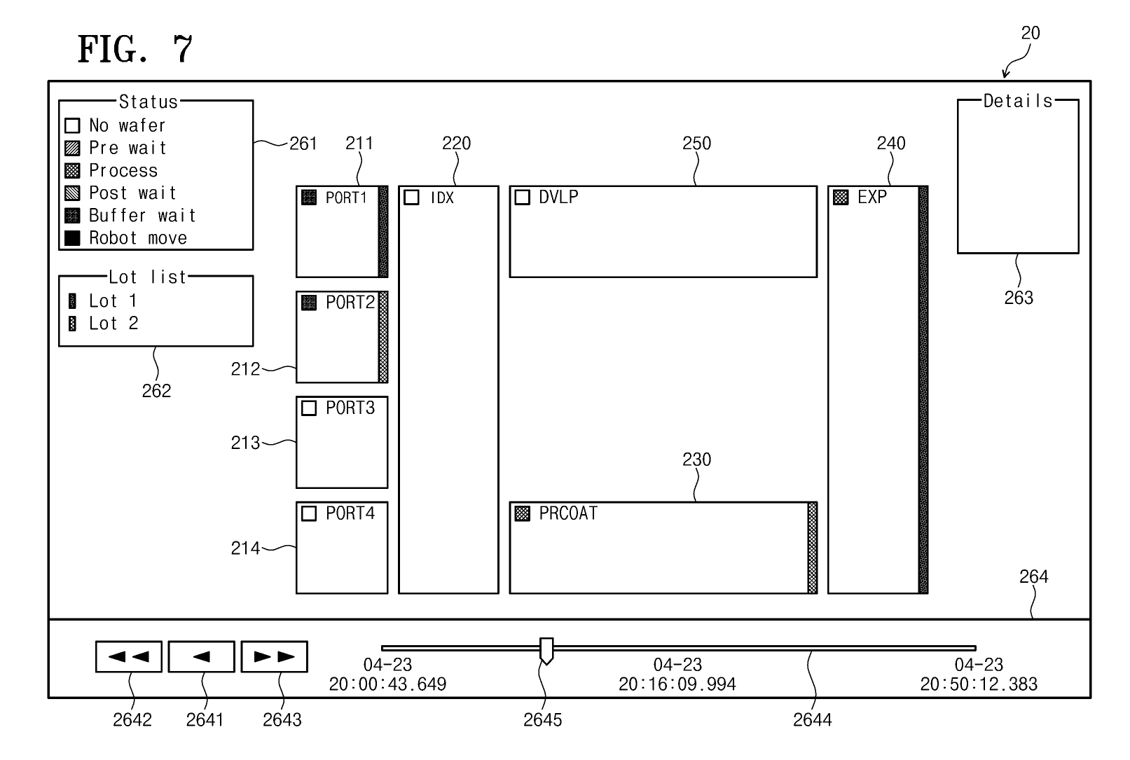

FIG. 7 is a view illustrating an operation of displaying the components 211 and 240, in which substrates belonging to a substrate group Lot 1 are distributed, differently from the other components 212, 213, 214, 220, 230, and 250, according to an embodiment of the inventive concept.

The substrate processing equipment 100 may process a plurality of substrates with one recipe, and the substrates processed with the same recipe may form a substrate group Lot 1 or Lot 2. The substrate processing equipment 100 may load a plurality of substrate groups processed with different recipes in the port modules 111, 112, 113, and 114 and may transfer and process the substrates belonging to the plurality of substrate groups according to a predetermined sequence.

In this regard, referring to FIG. 4, the process monitoring screen 20 may further provide a substrate group list 262 that includes the substrate groups Lot 1 and Lot 2 loaded in the substrate processing equipment 10 and subjected to substrate processing and indicators (e.g., colors) corresponding to the substrate groups Lot 1 and Lot 2.

In this embodiment, among the components 211, 212, 213, 214, 220, 230, 240, and 250 in the process monitoring screen 20, components in which a plurality of substrates belonging to a substrate group processed with the same recipe are distributed may be displayed differently from the other components (e.g., components in which substrates belonging to different substrate groups are distributed or components of modules in which no substrates are loaded) by the processing unit 203.

For example, referring to FIGS. 2 and 7, in the case where substrates belonging to the first substrate group Lot 1 are loaded in the first port module 111 of the substrate processing equipment 100, substrates belonging to the second substrate group Lot 2 are loaded in the second port module 112, the coating module 130 coats the substrates belonging to the second substrate group Lot 2 with a photosensitive material, and the exposure module 140 exposes the substrates belonging to the first substrate group Lot 1 to light, the substrate processing equipment 100 may transmit, to the substrate processing monitoring apparatus 200, process data including a message for providing notification that the substrates belonging to the first substrate group Lot 1 are stored in the first port module 111, the substrates belonging to the second substrate group Lot 2 are stored in the second port module 112, the coating module 130 processes the substrates belonging to the second substrate group Lot 2, and the exposure module 140 processes the substrates belonging to the first substrate group Lot 1.

According to the message included in the process data, the processing unit 203 may modify the visual states (e.g., the colors of the upper left areas) of the PORT 1 and PORT 2 components 211 and 212 corresponding to the first and second port modules 111 and 112 and may modify the visual states (e.g., the colors of the upper left areas) of the PRCOAT component 230 corresponding to the coating module 130 and the EXP component 240 corresponding to the exposure module 140. The processing unit 203 may distinguish between the visual states of other areas (e.g., the right areas) of the respective components according to the substrate groups Lot 1 and Lot 2 and may differently display the components in which the substrates belonging to the respective substrate groups are distributed.

That is, in FIG. 7, the processing unit 203 may display the upper left areas of the components 211, 212, 230, and 240, which correspond to the modules 111, 112, 130, and 140 in which the substrates are loaded, with any one color in the status list 261 and may display the right areas of the components 211, 212, 230, and 240 with any one color in the substrate group list 262. Accordingly, the process monitoring screen 20 may not only provide information about the modules of the substrate processing equipment 100 in which the substrates are loaded and processed, but may also provide information about the substrate groups to which the substrates loaded in the corresponding modules belong.

As a result, even though substrates belonging to substrate groups processed with different recipes are loaded and processed together in the substrate processing equipment 100, the substrate processing monitoring apparatus 200 may visually display the substrate group information of the substrates loaded and processed in the respective modules, thereby enabling a user to discern at a glance the positions of the substrates belonging to the different substrate groups Lot 1 and Lot 2 in the substrate processing equipment 100.

According to another embodiment of the inventive concept, when a component in the process monitoring screen 20 is selected, the processing unit 203 may display details of the module corresponding to the selected component on the process monitoring screen 20.

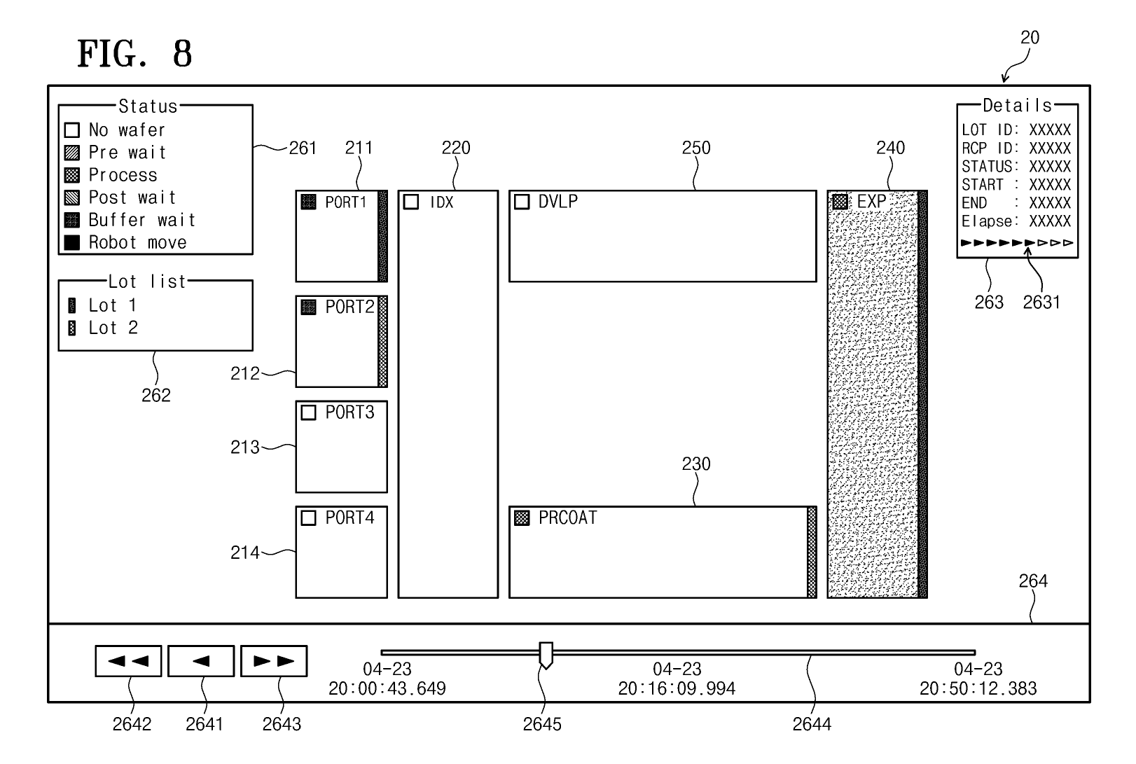

FIG. 8 is a view illustrating an operation of displaying details of the module 140 corresponding to the component 240 when the component 240 is selected, according to an embodiment of the inventive concept.

According to this embodiment, a user may select and activate any one of the components 211, 212, 213, 214, 220, 230, 240, and 250 displayed on the process monitoring screen 20.

For example, referring to FIG. 8, when the user selects the EXP component 240 in the process monitoring screen 20 via the input device 420, the EXP component 240 in the process monitoring screen 20 may be activated, and details 263 of the exposure module 140 corresponding to the relevant component may be displayed.

According to this embodiment, the details 263 may include at least one of the status (STATUS in FIG. 8) of the corresponding module 140 in the substrate processing equipment 100 that corresponds to the selected component 240, the identifier (LOT ID in FIG. 8) of a substrate group to which substrates located in the corresponding module 140 belong, the identifier (RCP ID in FIG. 8) of a recipe applied to the substrate group, status start time (START in FIG. 8) when the corresponding module 140 starts to have the status for the substrates, scheduled status end time (END in FIG. 8) when the status for the substrates is scheduled to end according to the recipe, and elapsed time (Elapse in FIG. 8) from the status start time. However, information about the module provided as the details 263 is not limited thereto.

In addition, the processing unit 203 may additionally display, on the process monitoring screen 20, an elapsed time indicator 2631 with a visual state variable depending on the elapsed time (Elapse), as the details 263 of the corresponding module 140.

Referring to FIG. 8, the elapsed time indicator 2631 may visually display elapsing of time by increasing the number of black triangles with an increase in the elapsed time. However, a method for implementing the elapsed time indicator 2631 is not limited thereto.

As described above, the substrate processing monitoring apparatus 200 may provide the substrate processing performed in the substrate processing equipment 100 to the user with the intuitive and easy-to-know graphic user interface (GUI) via the process monitoring screen 20 corresponding to the layout of the substrate processing equipment 100. As a result, the user may efficiently monitor the substrate processing performed in the substrate processing equipment 100 and may easily discern the process in which the substrates are transferred and processed in the substrate processing equipment 100.

In addition, according to an embodiment of the inventive concept, the processing unit 203 may generate a series of process monitoring screens 20 in which the visual states of the components 211, 212, 213, 213, 220, 230, 240, and 250 are varied as substrate processing is performed, as a reproducible process monitoring file.

For example, the processing unit 203 may capture the process monitoring screen 20 every preset time interval from the start time to the end time of substrate processing to configure a plurality of frames and may arrange the frames in a chronological order to generate one video file.

The process monitoring file may be stored in the storage unit 202. The process monitoring file may be loaded and reproduced in response to the user's request and may be displayed on the display device 410.

For example, referring to FIG. 4, the process monitoring screen 20 may have, at the bottom thereof, an area 264 associated with reproduction of the process monitoring file. A play button 2641, a rewind button 2642, a fast forward button 2643, a track bar 2644, and a play location indicator 2645 may be displayed in the area 264.

When the user selects the play button 2641 in the area 264 via the input device 420, the processing unit 203 may reproduce and output the process monitoring file on the display device 410. When the user selects the rewind button 2642, the processing unit 203 may reduce the play speed of the process monitoring file (e.g., to 0.5 times a normal speed), or may reproduce the processing monitoring file in the reverse direction. When the user selects the fast forward button 2643, the processing unit 203 may increase the play speed of the process monitoring file (e.g., to 2 times the normal speed). The play location indicator 2645 on the track bar 2644 may indicate the play time or location of part of the process monitoring file that is output on the display device 410 at present.

As described above, the substrate processing monitoring apparatus 200 may generate a series of process monitoring screens 20 in which the visual states of the components 211, 212, 213, 213, 220, 230, 240, and 250 are varied as substrate processing is performed, as a reproducible process monitoring file and may provide the process monitoring file to the user as a process monitoring result, thereby enabling the user to easily discern the progress of the substrate processing performed in the substrate processing equipment 100.

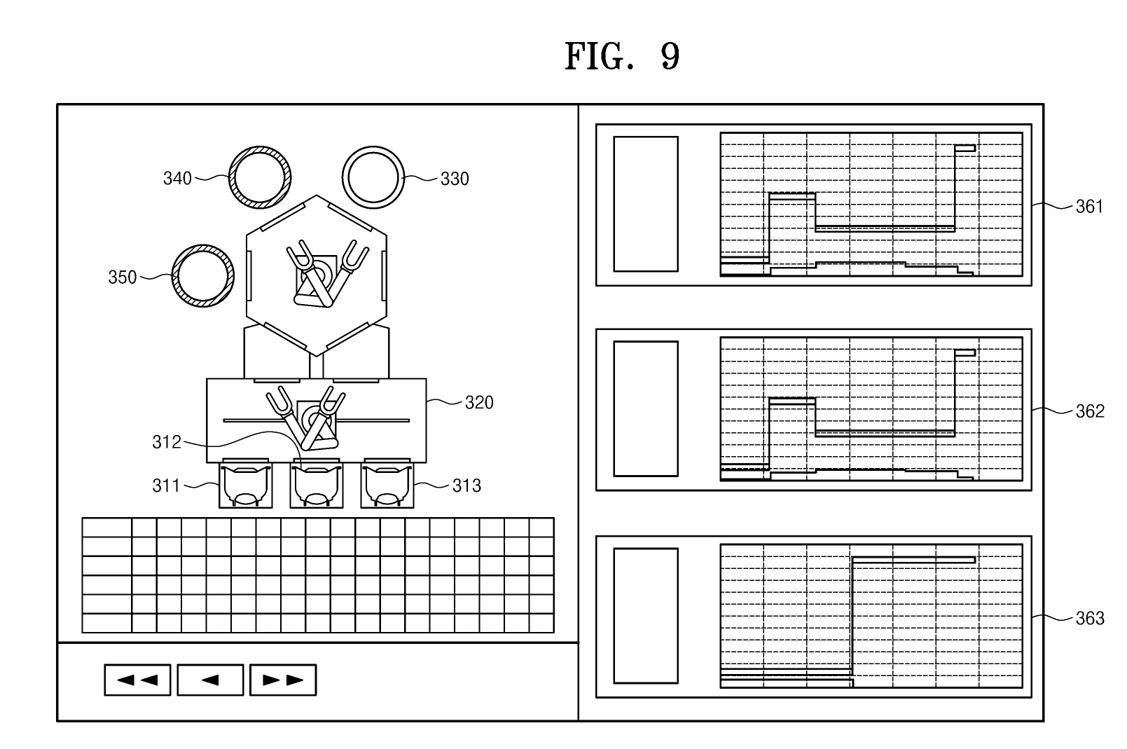

A process monitoring screen 20 according to another embodiment of the inventive concept may be provided as illustrated in FIG. 9. For example, as illustrated in FIG. 9, the process monitoring screen 20 may be configured such that components 311, 312, 313, 320, 330, 340, and 350 are disposed on a left side of the process monitoring screen 20 to correspond to the location of substrate processing equipment in which a process is performed and a process monitoring chart 361 at the time point when an abnormality occurred in the substrate processing equipment and a process monitoring chart 363 at the current time point are disposed on a right side of the process monitoring screen 20. In addition, a process monitoring chart 362 at a specific time point desired by a user may be disposed on a right side of the process monitoring screen 20. Accordingly, when an abnormality occurs in the substrate processing equipment, the user may easily discern where and when the abnormality occurs in the substrate processing equipment and may efficiently compare process data at the time of the occurrence of the abnormality with process data at a different time point.

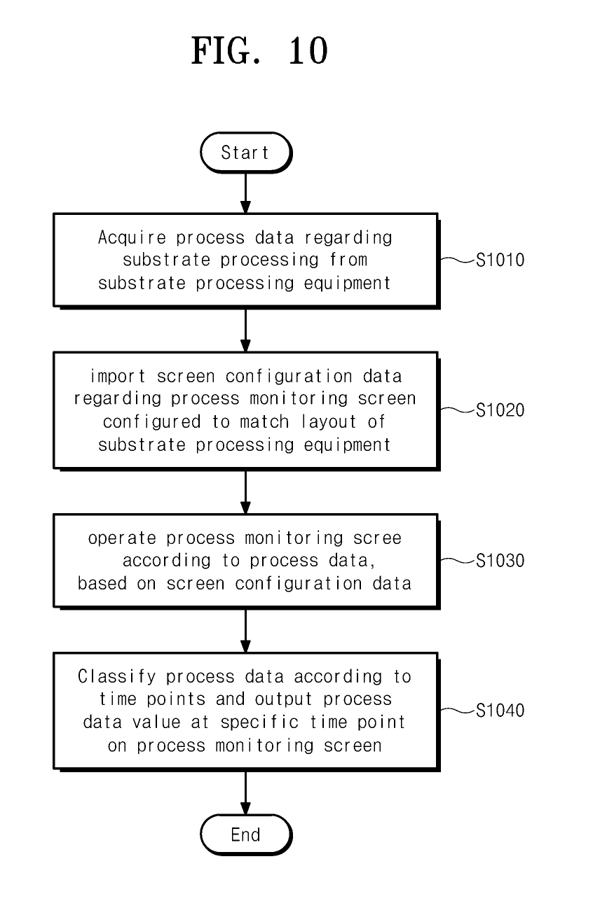

FIG. 10 is a flowchart illustrating a method for monitoring substrate processing according to an embodiment of the inventive concept.

First, a substrate processing monitoring apparatus may acquire process data regarding substrate processing from substrate processing equipment (Step S1010). Here, the process data may include module identification data for identifying a module in which an event occurs, event identification data for identifying the event, event start time data regarding the time when the event starts, and event end time data regarding the time when the event ends.

Next, the substrate processing monitoring apparatus may import screen configuration data regarding a process monitoring screen that is configured to match the layout of the substrate processing equipment (Step S1020). In this case, the substrate processing monitoring apparatus may import screen configuration data regarding at least one component included in the process monitoring screen to correspond to at least one module included in the substrate processing equipment and the arrangement of the component in the process monitoring screen.

Then, the substrate processing monitoring apparatus may operate the process monitoring screen according to the process data, based on the screen configuration data (Step S1030). Specifically, based on the screen configuration data, the substrate processing monitoring apparatus may configure the process monitoring screen in which the component is disposed. The substrate processing monitoring apparatus may modify the visual state of the component corresponding to the relevant module according to data indicating an event of the module that is included in the process data.

After that, the substrate processing monitoring apparatus may classify the process data according to time points and may output a process data value at a specific time point on the process monitoring screen (Step S1040). Specifically, the substrate processing monitoring apparatus may compare the process data with a pre-stored normal status value to determine whether the substrate processing equipment is abnormal or not. In the case where the substrate processing equipment is abnormal, the substrate processing monitoring equipment may output a process monitoring screen at the time point when the abnormality occurred in the substrate processing equipment. Accordingly, a user may easily discern where and when the abnormality occurred in the substrate processing equipment.

The substrate processing monitoring method may be made as a program to be executed on a computer and may be stored on a computer-readable recording medium. The computer-readable recording medium may include all kinds of storage devices for storing data that can be read by a computer system. Examples of the computer-readable recording medium may include a ROM, a RAM, a CD-ROM, a magnetic tape, a floppy disk, and an optical data storage device. In addition, the substrate processing monitoring method may be implemented as a computer program stored on a medium for execution in association with the computer.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for monitoring substrate processing, the apparatus comprising:
a process data acquisition unit configured to acquire process data regarding the substrate processing from substrate processing equipment;
a storage unit configured to store screen configuration data regarding a process monitoring screen that is configured to match a layout of the substrate processing equipment;
a processing unit configured to import the screen configuration data and operate the process monitoring screen according to the process data; and
a control unit configured to classify the process data according to time points and output a process data value at a specific time point on the process monitoring screen.

2. The apparatus of claim 1, wherein the control unit compares the process data with a pre-stored normal status value to determine whether the substrate processing equipment is abnormal or not, and when it is determined that the substrate processing equipment is abnormal, the control unit outputs the process monitoring screen at a time point when the abnormality occurred in the substrate processing equipment.

3. The apparatus of claim 2, wherein the process data acquisition unit acquires the process data indicating an event that occurs in at least one module included in the substrate processing equipment as the substrate processing is performed.

4. The apparatus of claim 3, wherein the process data includes:
module identification data for identifying the module in which the event occurs;
event identification data for identifying the event;
event start time data regarding time when the event starts; and
event end time data regarding time when the event ends.

5. The apparatus of claim 2, wherein the storage unit stores the screen configuration data regarding at least one component included in the process monitoring screen to correspond to at least one module included in the substrate processing equipment and an arrangement of the at least one component in the process monitoring screen.

6. The apparatus of claim 5, wherein the screen configuration data is configured such that the at least one component is disposed in the process monitoring screen in an order of the at least one module through which a substrate passes along a transfer path in the substrate processing equipment.

7. The apparatus of claim 6, wherein the processing unit generates a process monitoring chart showing a status of a substrate processed by the substrate processing equipment during the substrate processing over time.

8. The apparatus of claim 7, wherein the screen configuration data is configured such that the at least one component is disposed on a side of the process monitoring screen and the process monitoring chart at the time point when the abnormality occurred in the substrate processing equipment and the process monitoring chart at a current time point are disposed on an opposite side of the process monitoring screen.

9. A method for monitoring, by a substrate processing monitoring apparatus, substrate processing performed in substrate processing equipment, the method comprising:
acquiring process data regarding the substrate processing from the substrate processing equipment;
importing screen configuration data regarding a process monitoring screen that is configured to match a layout of the substrate processing equipment;
operating the process monitoring screen according to the process data, based on the screen configuration data; and
classifying the process data according to time points and outputting a process data value at a specific time point on the process monitoring screen.

10. The method of claim 9, wherein the outputting of the process data value at the specific time point on the process monitoring screen includes:
comparing the process data with a pre-stored normal status value to determine whether the substrate processing equipment is abnormal or not; and
outputting the process monitoring screen at a time point when the abnormality occurred in the substrate processing equipment, when it is determined that the substrate processing equipment is abnormal.

11. The method of claim 10, wherein the acquiring of the process data includes:
acquiring the process data indicating an event that occurs in at least one module included in the substrate processing equipment as the substrate processing is performed.

12. The method of claim 11, wherein the process data includes:
module identification data for identifying the module in which the event occurs;
event identification data for identifying the event;
event start time data regarding time when the event starts; and
event end time data regarding time when the event ends.

13. The method of claim 10, wherein the importing of the screen configuration data includes:
importing the screen configuration data regarding at least one component included in the process monitoring screen to correspond to at least one module included in the substrate processing equipment and an arrangement of the at least one component in the process monitoring screen.

14. The method of claim 13, wherein the screen configuration data is configured such that the at least one component is disposed in the process monitoring screen in an order of the at least one module through which a substrate passes along a transfer path in the substrate processing equipment.

15. The method of claim 14, wherein the operating of the process monitoring screen includes:
configuring the process monitoring screen in which the at least one component is disposed, based on the screen configuration data; and
modifying a visual state of the at least one component corresponding to the at least one module according to data indicating an event of the at least one module that is included in the process data.

16. The method of claim 15, further comprising:
generating a process monitoring chart showing a status of at least one substrate processed by the substrate processing equipment during the substrate processing over time.

17. The method of claim 16, wherein the screen configuration data is configured such that the at least one component is disposed on a side of the process monitoring screen and the process monitoring chart at the time point when the abnormality occurred in the substrate processing equipment and the process monitoring chart at a current time point are disposed on an opposite side of the process monitoring screen.

18. The method of claim 16, wherein the generating of the process monitoring chart includes:
generating the process monitoring chart by displaying time according to the progress of the substrate processing along one axis of the process monitoring chart and displaying the status of the at least one substrate along another axis of the process monitoring chart.

19. A computer-readable recording medium configured to store a program for executing the method according to claim 9.

20. A computer program stored in a recording medium to execute the method according to claim 9.
